(19) United States
(12) Patent Application Publication
(10) Pub. No.: US 2025/0038718 A1
(43) Pub. Date: Jan. 30, 2025

(54) ANALOG FRONT-END CIRCUIT AND OFFSET VOLTAGE CORRECTION METHOD THEREOF

(71) Applicant: Montage Technology (Kunshan) Co., Ltd., Suzhou (CN)

(72) Inventors: Jian Yin, Suzhou (CN); Lixin Jiang, Suzhou (CN); Kang Wei, Suzhou (CN)

(73) Assignee: Montage Technology (Kunshan) Co., Ltd., Suzhou (CN)

(21) Appl. No.: 18/741,796

(22) Filed: Jun. 13, 2024

(30) Foreign Application Priority Data
Jul. 11, 2023 (CN) 202310847153.9

(51) Int. Cl. H03F 3/45

(52) U.S. Cl. CPC H03F 3/45744; H03F 3/45183; H03F 2200/261; H03F 2200/375

(57) ABSTRACT

Disclosed are an analog front-end (AFE) circuit and an offset voltage correction method thereof. The offset voltage correction method includes: obtaining the first offset voltage generated by the differential input transistor pair of the first amplifier in the AFE circuit, and generating first information according to the first offset voltage; obtaining a second offset voltage generated by a tail current source of the first amplifier in the AFE circuit, and generating second information according to the second offset voltage and the first information; obtaining a predetermined first DC gain and a predetermined second DC gain, and generating first compensation information by performing calculation based on the first DC gain, the second DC gain, the first information and the second information; and correcting an output voltage generated by the first amplifier based on the first compensation information.

### CROSS-REFERENCE TO RELATED APPLICATION

This application claims the priority benefit of China application serial no. 202310847153.9, filed on Jul. 11, 2023. The entirety of the above-mentioned patent application is hereby incorporated by reference herein and made a part of this specification.

### BACKGROUND

### Technical Field

The present disclosure relates to an analog front-end circuit and an offset voltage correction method thereof, and in particular to an analog front-end circuit that may save circuit area and an offset voltage correction method thereof.

### Description of Related Art

There are two common methods for correcting the offset voltage of analog front-end (AFE) circuits. One of the correction methods may be used in an AFE circuit with programmable capabilities to correct the offset voltage by programming various gain settings. Such correction method normally requires a long training time to perform corrections on various gains, which reduces the training speed of the circuit.

The other correction method may be used in AFE circuits that do not have programmability. A test machine performs correction operations on the AFE circuit to correct the offset voltage corresponding to various gain settings, and generates multiple corresponding correction codes, so that the AFE circuit performs correction operations according to the correction codes. Such method requires a long test time before the chips are shipped out of the factory, causing an increase in test costs. Moreover, this method will generate a large number of correction codes, and a large amount of storage space is required to store the correction codes, resulting in a waste of circuit area.

### SUMMARY

The disclosure relates to an analog front-end (AFE) circuit and an offset voltage correction method thereof, which may reduce the area required for the circuit.

According to an embodiment of the present disclosure, the offset voltage correction method is applicable to the AFE circuit. The offset voltage correction method includes: obtaining a first offset voltage generated by a differential input transistor pair of a first amplifier in an AFE circuit, and generating first information according to the first offset voltage; obtaining a second offset voltage generated by a tail current source of the first amplifier in the AFE circuit, and generating second information according to the second offset voltage and the first information; obtaining a predetermined first DC gain and a predetermined second DC gain, and generating first compensation information based on the first DC gain, the second DC gain, the first information and the second information; and correcting an output voltage generated by the first amplifier based on the first compensation information.

According to an embodiment of the present disclosure, an AFE circuit includes a first amplifier, a first compensation circuit and a compensation information generator. The first compensation circuit is coupled to an output terminal of the first amplifier and corrects a first output voltage generated by the first amplifier according to first compensation information. The compensation information generator is coupled to the first compensation circuit and generates the first compensation information according to a first DC gain, a second DC gain, first information and second information, wherein the first information is generated based on a first offset voltage generated by a differential input transistor pair of the first amplifier, and the second information is generated based on a second offset voltage generated by a tail current source of the first amplifier.

### BRIEF DESCRIPTION OF THE DRAWINGS

FIG. 1 shows a flow chart of an offset voltage correction method according to an embodiment of the present disclosure.

FIG. 2 shows a schematic view of the causes of offset voltage in amplifiers.

FIG. 3 shows a schematic view of an analog front-end (AFE) circuit according to an embodiment of the present disclosure.

FIG. 4 shows a schematic view of a compensation information generator in the AFE circuit according to an embodiment of the present disclosure.

FIG. 5 shows a schematic view of an AFE circuit according to another embodiment of the present disclosure.

FIG. 6 shows a flow chart of an offset voltage correction method according to an embodiment of the present disclosure.

FIG. 7 shows a circuit diagram of an AFE circuit according to another embodiment of the present disclosure.

FIG. 8 shows a schematic view of an implementation of a compensation information generation circuit of an AFE circuit according to an embodiment of the present disclosure.

### DESCRIPTION OF THE EMBODIMENTS

Reference will now be made in detail to the exemplary embodiments of the present disclosure, examples of which are illustrated in the accompanying drawings. Whenever possible, the same reference numbers are used in the drawings and descriptions to refer to the same or similar parts.

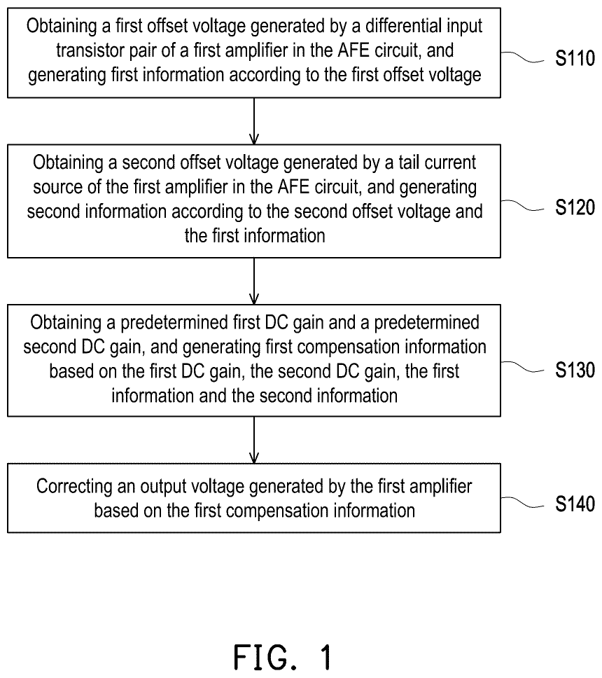

Please refer to FIG. 1, which shows a flow chart of an offset voltage correction method according to an embodiment of the present disclosure. The offset voltage correction method of this embodiment is suitable for analog front-end (AFE) circuits. The AFE circuit may be disposed in a signal receiver, for example. One or more amplifiers may be included in the AFE circuit. In step S110, a first offset voltage generated by a differential input transistor pair of a first amplifier in the AFE circuit is obtained, and first information is generated based on the first offset voltage. Furthermore, in step S120, a second offset voltage generated by a tail current source of the first amplifier in the AFE circuit is obtained, and second information is generated based on the second offset voltage and the first information. Next, in step S130, a preset first DC gain and a preset second DC gain are obtained, and first compensation information is generated based on the first DC gain, the second DC gain, the first information and the second information. Moreover, in step S140, an output voltage generated by the first amplifier is corrected according to the first compensation information.

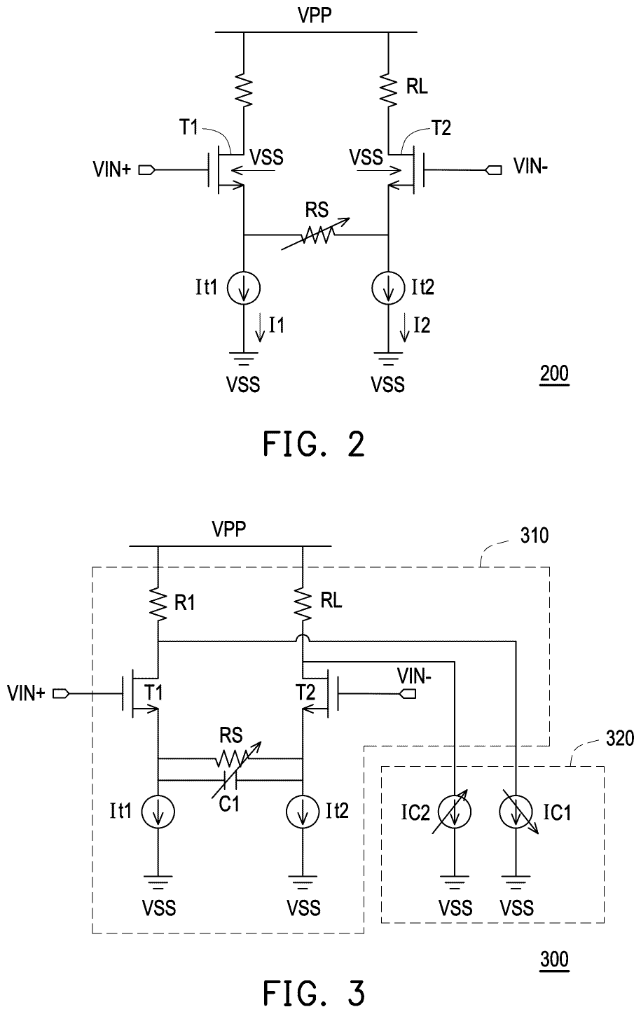

For details of the above correction method, please first refer to FIG. 2, which shows a schematic view of an amplifier according to an embodiment of the present disclosure. The causes of the first offset voltage and the second offset voltage will be described below with reference to FIG. 2. In FIG. 2, an amplifier 200 includes transistors T1 and T2, tail current sources It1 and It2, a source resistor Rs and a load resistor RL. The transistors T1 and T2 form a differential input transistor pair, and gates of the transistors T1 and T2 receive input signals Vin+ and Vin− respectively. The tail current source It1 is coupled between a source of the transistor T1 and a reference ground terminal VSS, and the tail current source It2 is coupled between a source of the transistor T2 and the reference ground terminal VSS. The tail current source It1 is adopted to generate a tail current I1. The tail current source It2 is adopted to generate a tail current I2.

Furthermore, the amplifier 200 has a source resistor Rs. The source resistor Rs is coupled between the source of the transistor T1 and the source of the transistor T2, wherein the source resistor Rs may be a variable resistor. The amplifier 200 further has a load resistor RL, which is coupled between a drain of the transistor T2 and a power terminal VPP. In this embodiment, substrates of the transistors T1 and T2 are coupled to the reference ground terminal VSS, for example.

The offset voltage of the amplifier 200 may be originated from the differential input transistor pair thereof and from the tail current sources It1 and It2. The first offset voltage generated by the change in threshold voltages of the transistors T1 and T2 (the threshold voltages change relative to the standard value due to process manufacturing adaptation) may be equal to

$$\frac{gm \times RL}{1 + gm \times Rs / 2} \cdot \sqrt{2} \cdot Vth\_mis ,$$

wherein gm is transconductance values of transistors T1 and T2, and Vth_mis is a change in the threshold voltages of the transistors T1 and T2 relative to the standard value.

$$\frac{gm \times RL}{1 + gm \times Rs / 2}$$

is related to the design structure of the circuit, while Vth_mis is related to the manufacturing process. In addition, the second offset voltage caused by the tail current sources It1 and It2 is equal to

$$\frac{gm \times Rs / 2}{1 + gm \times Rs / 2} \cdot RL \cdot \sqrt{2} \cdot Imis ,$$

wherein Imis is the change in tail current.

$$\frac{gm \times Rs / 2}{1 + gm \times Rs / 2}$$

is related to the design structure of the circuit, and Imis is related to the manufacturing process.

In this embodiment, the first DC gain value mentioned in the embodiment of FIG. 1 may be determined according to

$$\frac{gm \times RL}{1 + gm \times Rs / 2} ,$$

and the second DC gain value may be determined according to

$$\frac{gm \times Rs / 2}{1 + gm \times Rs / 2} .$$

When the circuit structure is determined, the first DC gain and the second DC gain are fixed values. The overall offset voltage of the amplifier 200 may be equal to Pa1×Vos1+Pb1×Vos2, wherein Pa1 and Pb1 are the first DC gain and the second DC gain respectively, and Vos1 and Vos2 are the first information and the second information respectively. The first DC gain Pa1 and the second DC gain Pb1 may be calculated in advance after the design is completed. Pa1 and Pb1 are controlled by an amplifier gain setting digital code. Different gain settings correspond to different Pa1 and Pb1, and the specific values are determined and ensured by the design.

Please refer to FIG. 3 below. FIG. 3 shows a schematic view of an AFE circuit according to an embodiment of the present disclosure. An AFE circuit 300 includes an amplifier 310 and a compensation circuit 320. The amplifier 310 includes transistors T1 and T2, the source resistor Rs, the load resistor RL, a resistor R1, a capacitor C1, and the tail current sources It1 and It2. The transistors T1 and T2 form the differential input transistor pair. The tail current source It1 is coupled between the source of the transistor T1 and the reference ground terminal VSS, and the tail current source It2 is coupled between the source of the transistor T2 and the reference ground terminal VSS. The source resistor Rs is coupled between the source of the transistor T1 and the source of the transistor T2. The capacitor C1 and the source resistor Rs are coupled in parallel with each other. In this embodiment, the source resistor Rs may be a variable resistor, and the capacitor C1 may be a variable capacitor.

In addition, the load resistor RL is coupled between the drain of the transistor T2 and the power terminal VPP, and the resistor R1 is coupled between the drain of the transistor T1 and the power terminal VPP. A coupling point between the resistor R1 and the transistor T1 may be used as a first output terminal of the amplifier 310, and a coupling point between the load resistor RL and the transistor T2 may be used as a second output terminal of the amplifier 310. The first output terminal and the second output terminal are mutually inverted output terminals, and together form a differential output signal.

The compensation circuit 320 is coupled to the first output terminal and the second output terminal. The compensation circuit 320 includes current sources IC1 and IC2. The current source IC1 is coupled between the first output terminal and the reference ground terminal VSS, and the current source IC2 is coupled between the second output terminal and the reference ground terminal VSS.

In the embodiment, the current source IC1 provides a first compensation current for the first output terminal of the amplifier 310 based on the first compensation information, and the current source IC2 provides a second compensation current for the second output terminal of the amplifier 310 based on the first compensation information. Through the first compensation current and the second compensation current, the compensation circuit 320 may compensate the output voltage of the amplifier 310. The first compensation information is as described in the embodiment of FIG. 1 and will not be described in detail here. In addition, it should be noted that the embodiment of the present disclosure takes the current compensation method as an example, but those skilled in the art can understand that the present disclosure may also adopt the voltage compensation method, and the present disclosure provides no limitation thereto.

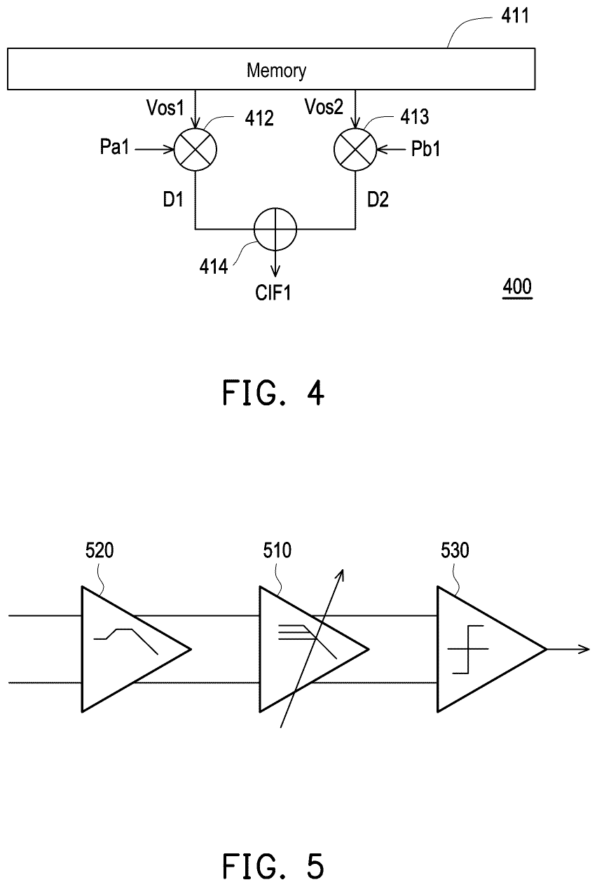

Please refer to FIG. 4 below. FIG. 4 shows a schematic view of the compensation information generator (also referred to as a compensation information generation circuit) in the AFE circuit according to an embodiment of the present disclosure. In FIG. 4, a compensation information generator 400 includes a memory 411, multipliers 412 and 413 and an adder 414. The memory 411 is configured to store the first information Vos1 and the second information Vos2. According to the embodiment of FIG. 1, the first information Vos1 may be obtained according to the first offset voltage generated by the differential input transistor pair of the amplifier, and the second information Vos2 may be obtained according to the second offset voltage generated by the tail current source and the first information Vos1. The multipliers 412 and 413 are coupled to memory 411. The multiplier 412 receives the first information Vos1 and the first DC gain Pa1, and multiplies the first information Vos1 by the first DC gain Pa1 to generate a first data D1. The multiplier 413 receives the second information Vos2 and the second DC gain Pa2, and multiplies the second information Vos2 by the second DC gain Pa2 to generate a second data D2.

The adder 414 is coupled to the multipliers 412 and 413. The adder 414 adds the first data D1 and the second data D2 and generates the first compensation information CIF1. In this embodiment, the first compensation information CIF1 may be provided to the current sources IC1 and IC2 in the compensation circuit 320 in the embodiment of FIG. 3, so that the current sources IC1 and IC2 compensate the output voltage.

Please refer to FIG. 5 below, which shows a schematic view of an AFE circuit according to another embodiment of the present disclosure. An AFE circuit 500 includes a first amplifier 510, a second amplifier 520 and a comparator 530. The second amplifier 520 is coupled to an input terminal of the first amplifier 510, and the comparator 530 is coupled to an output terminal of the first amplifier 510. In this embodiment, the second amplifier 520 may be a continuous time linear equalizer (CTLE), and the first amplifier 510 may be a variable gain amplifier (VGA).

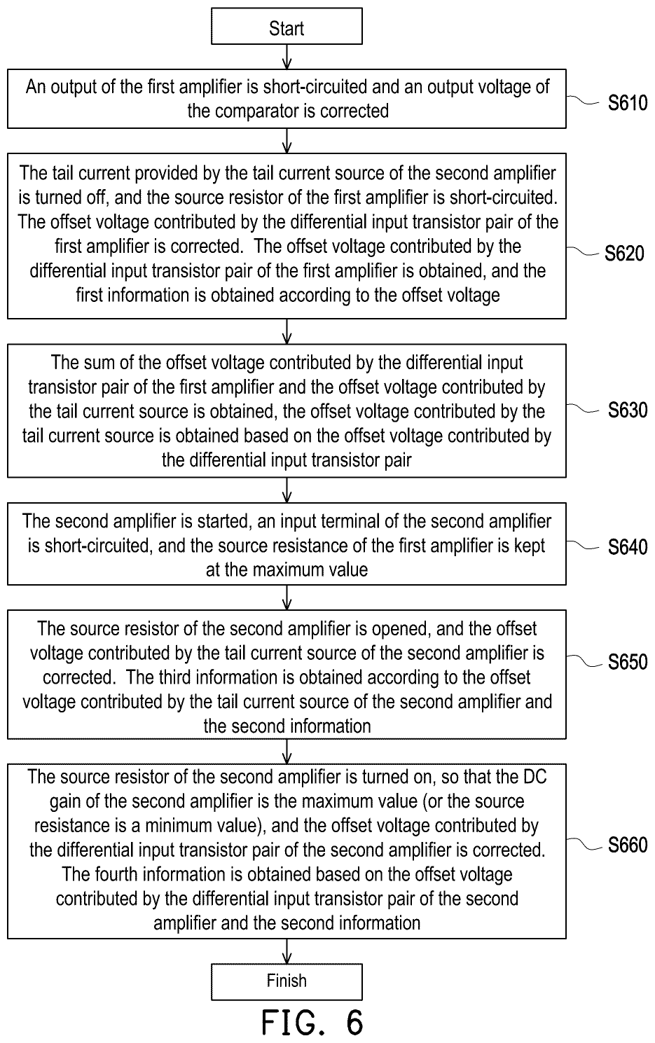

Regarding the offset voltage correction method of the AFE circuit 500, reference may be made to the embodiment of FIG. 6, wherein FIG. 6 shows a flow chart of the offset voltage correction method of the embodiment of the present disclosure. In step S610, an output of the first amplifier 510 may be short-circuited and an output voltage of the comparator 530 may be corrected. Then, in step S620, the tail current provided by the tail current source of the second amplifier 520 may be turned off, and the source resistor of the first amplifier 510 may be short-circuited. In this way, the offset voltage contributed by the differential input transistor pair of the first amplifier 510 may be corrected. In step S620, the offset voltage contributed by the differential input transistor pair of the first amplifier 510 may be obtained, and the first information may be obtained according to the offset voltage.

In step S630, the sum of the offset voltage contributed by the differential input transistor pair of the first amplifier 510 and the offset voltage contributed by the tail current source may be obtained, the offset voltage contributed by the tail current source may be obtained based on the offset voltage contributed by the differential input transistor pair obtained in step S620, and the second information may be obtained according to the offset voltage contributed by the tail current source and the first information. In this embodiment, the first information, the second information, the first DC gain, the second DC gain, the first compensation information, the second compensation information, etc. may all be digital values (for example, binary integers with signed bits), and may be written to any form of memory.

In step S640, the second amplifier 520 is started, an input terminal of the second amplifier 520 is short-circuited, and the source resistance of the first amplifier is kept at the maximum value. Next, in step S650, the source resistor Rs of the second amplifier 520 is opened (that is, the circuit of the source resistor Rs between the sources of the transistor T1 and the transistor T2 is disconnected), and the offset voltage contributed by the tail current source of the second amplifier 520 is corrected. The third information may be obtained according to the offset voltage contributed by the tail current source of the second amplifier 520 and the second information.

In step S660, the source resistor of the second amplifier 520 is turned on (that is, the circuit of the source resistor Rs between the sources of the transistor T1 and the transistor T2 is connected), so that the DC gain of the second amplifier 520 is the maximum value (or the source resistance is a minimum value), and the offset voltage contributed by the differential input transistor pair of the second amplifier 520 is corrected. The fourth information may be obtained based on the offset voltage contributed by the differential input transistor pair of the second amplifier 520 and the second information.

Similarly, in this embodiment, both the third information and the fourth information may be digital values, and may be written into any form of memory.

Regarding the above-mentioned steps S610 to S660, a test machine may be used to obtain the values of the above-mentioned offset voltages, and the status of the first amplifier and the second amplifier in the AFE circuit may be controlled by sending test commands to perform the measurement operation on various offset voltages, and the required information may be obtained based on the measured offset voltage. Alternatively, in other embodiments of the present disclosure, a self-test circuit may be built into the chip, and measurement operations on various offset voltage may be completed by built-in self-test. The embodiment of the present disclosure is not limited thereto.

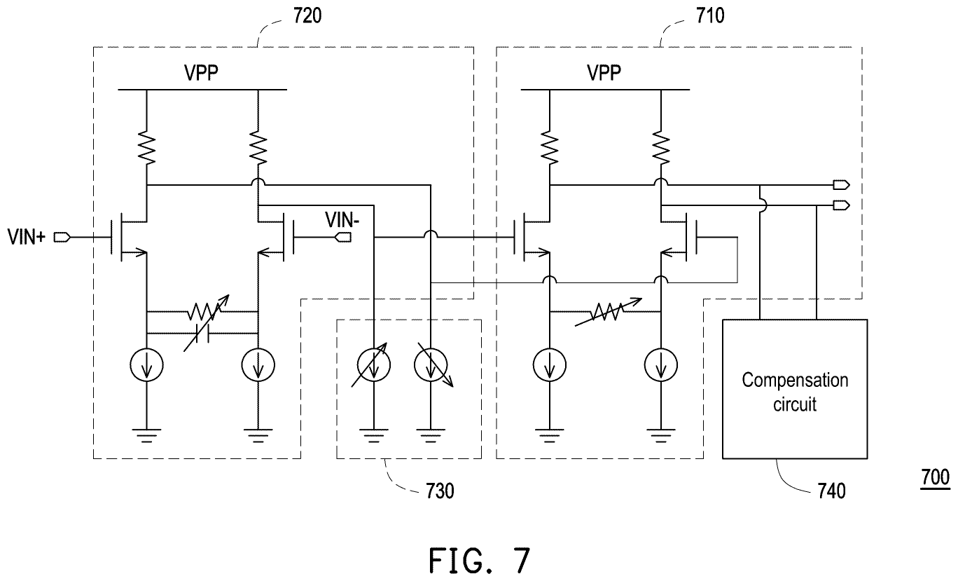

Please refer to FIG. 7, which shows a circuit diagram of an AFE circuit according to another embodiment of the present disclosure. An AFE circuit 700 includes a first amplifier 710, a second amplifier 720, and compensation circuits 730 and 740. The first amplifier 710 is coupled after the second amplifier 720. The compensation circuit 730 is coupled to an output terminal of the second amplifier 720, and the compensation circuit 740 is coupled to the output terminal of the second amplifier 710. The second amplifier 720 is, for example, a CTLE, and the first amplifier 710 is, for example, a variable gain amplifier.

Corresponding to the flow chart of FIG. 6, according to the first information and the second information generated in steps S620 and S630 as well as the first DC gain and the second DC gain calculated in advance, the first compensation information corresponding to the first amplifier 710 is calculated. The compensation circuit 740 may compensate an output voltage of the first amplifier 710 according to the first compensation information. In addition, according to the third information and the fourth information generated in steps S650 and S650 as well as the third DC gain and the fourth DC gain calculated in advance, the second compensation information corresponding to the second amplifier 720 is calculated. The compensation circuit 730 may compensate an output voltage of the second amplifier 720 according to the second compensation information.

In other embodiments of the present disclosure, the AFE circuit 700 may not be provided with the compensation circuit 730, but only be provided with the compensation circuit 740. Third compensation information may be generated according to the first compensation information and the second compensation information. The compensation circuit 740 may perform a one-time compensation action on an output voltage of the AFE circuit 700 according to the third compensation information, thereby effectively saving a circuit area.

Those skilled in the art can understand that the method of the present disclosure is not limited to FIG. 1 and FIG. 6 and the specific order described above. It should be understood that in other embodiments, the order of some steps may be switched according to actual needs, or some of these steps may also be omitted or deleted.

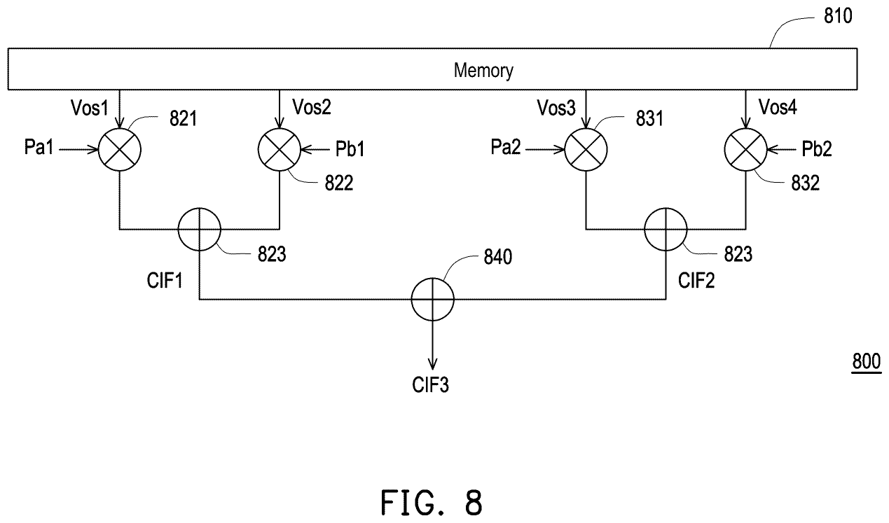

Regarding the method of generating the compensation information in the above embodiment, please refer to FIG. 8, wherein FIG. 8 shows a schematic view of the implementation of the compensation information generation circuit of the AFE circuit according to the embodiment of the present disclosure. The compensation information generation circuit 800 includes a memory 810, multipliers 821, 822, 831, and 832, and adders 823, 833, and 840. The memory 810 is configured to store the first information Vos1, the second information Vos2, the third information Vos3 and the fourth information Vos4 in the embodiment of FIG. 6. The multipliers 821, 822, 831, and 832 are coupled to memory 810.

In terms of operation details, the multiplier 821 receives the first information Vos1 and the first DC gain Pa1, and multiplies the first information Vos1 by the DC gain Pa1 to generate first data. The multiplier 822 receives the second information Vos2 and the DC gain Pb2, and multiplies the second information Vos2 by the DC gain Pb2 to generate second data. The adder 823 is coupled to the multipliers 821 and 822. The adder 823 adds the first data and the second data to generate first compensation information CIF1.

On the other hand, the multiplier 831 receives the third information Vos3 and the DC gain Pa2, and multiplies the third information Vos3 by the DC gain Pa2 to generate third data. The multiplier 832 receives the fourth information Vos4 and the DC gain Pb2, and multiplies the fourth information Vos4 by the DC gain Pb2 to generate fourth data. The adder 833 is coupled to the multipliers 831 and 832. The adder 833 adds the third data and the fourth data to generate second compensation information CIF2.

The adder 840 is coupled to the adders 823 and 833 for adding the first compensation information CIF1 and the second compensation information CIF2 to generate the compensation information CIF3.

In this embodiment, the multipliers 821, 822, 831, and 832 and the adders 823, 833 and 840 may be common multiplication circuits and addition circuits of digital circuits, the present disclosure provides no limitation thereto.

Based on the above description, the AFE circuit of the present disclosure obtains various parameters by respectively obtaining the offset voltages contributed by the differential input transistor pairs and tail current sources of the amplifiers at various stages, and generates multiple compensation information accordingly, thereby effectively completing the correction of the offset voltage of the AFE circuit under different gain settings through the compensation information. The AFE circuit of the embodiment of the present disclosure does not need to use a large amount of storage space to store correction information corresponding to multiple different gains respectively, thus making it possible to effectively reduce circuit space. Moreover, the AFE circuit of the embodiment of the present disclosure does not need to spend a lot of time to perform training actions, which facilitates the efficiency of circuit operation.

Finally, it should be noted that the above embodiments are only used to illustrate the technical solution of the present disclosure, but not to limit it. Although the present disclosure has been described in detail with reference to the foregoing embodiments, those of ordinary skill in the art should understand that: The technical solutions described in the foregoing embodiments can still be modified, or some or all of the technical features can be equivalently replaced; and these modifications or substitutions do not deviate from the essence of the corresponding technical solutions from the scope of the technical solutions of the embodiments of the present disclosure.

What is claimed is:

1. An offset voltage correction method, adaptable for an analog front-end (AFE) circuit, comprising:
obtaining a first offset voltage generated by a differential input transistor pair of a first amplifier in the AFE circuit, and generating first information according to the first offset voltage;
obtaining a second offset voltage generated by a tail current source of the first amplifier in the AFE circuit, and generating second information according to the second offset voltage and the first information;
obtaining a predetermined first DC gain and a predetermined second DC gain, and generating first compensation information based on the first DC gain, the second DC gain, the first information and the second information; and
correcting an output voltage generated by the first amplifier based on the first compensation information.

2. The offset voltage correction method according to claim 1, further comprising:
turning off the first amplifier and compensating an output voltage of a comparator, wherein the comparator is coupled after the first amplifier.

3. The offset voltage correction method according to claim 1, wherein the step of generating the first compensation information based on the first DC gain, the second DC gain, the first information and the second information comprises:
multiplying the first DC gain by the first information to obtain first data;
multiplying the second DC gain by the second information to obtain second data; and
adding the first data and the second data to obtain the first compensation information.

4. The offset voltage correction method according to claim 1, wherein the first DC gain is equal to
$$\frac{gm \times RL}{1 + gm \times Rs / 2} ,$$
and the second DC gain is equal to
$$\frac{gm \times Rs / 2}{1 + gm \times Rs / 2} ,$$
wherein gm is a transconductance value of the first amplifier, Rs is a source resistance value in the first amplifier, and RL is a load resistance value of the first amplifier.

5. The offset voltage correction method according to claim 1, further comprising:
obtaining a third offset voltage generated by a tail current source of a second amplifier in the AFE circuit, and generating third information based on the third offset voltage and the second information;
obtaining a fourth offset voltage generated by a differential input transistor pair of the second amplifier in the AFE circuit, and generating fourth information based on the fourth offset voltage and the second information;
generating second compensation information according to a predetermined third DC gain, a predetermined fourth DC gain, the third information and the fourth information;
correcting an output voltage generated by the second amplifier based on the second compensation information,
wherein the second amplifier is coupled before the first amplifier.

6. The offset voltage correction method according to claim 5, further comprising:
writing the first information, the second information, the third information and the fourth information into a memory.

7. An analog front-end (AFE) circuit, comprising:
a first amplifier;
a first compensation circuit coupled to an output terminal of the first amplifier, correcting an output voltage generated by the first amplifier according to first compensation information; and
a compensation information generator coupled to the first compensation circuit, generating the first compensation information according to a first DC gain, a second DC gain, first information and second information,
wherein the first information is generated based on a first offset voltage generated by a differential input transistor pair of the first amplifier, and the second information is generated based on a second offset voltage generated by a tail current source of the first amplifier.

8. The AFE circuit according to claim 7, wherein the first compensation circuit comprises:
a first current source coupled between a first output terminal of the first amplifier and a reference ground terminal, providing a first compensation current to a first output terminal of the first amplifier according to the first compensation information; and
a second current source coupled between a second output terminal of the first amplifier and the reference ground terminal, providing a second compensation current to a second output terminal of the first amplifier according to the first compensation information.

9. The AFE circuit according to claim 7, wherein the compensation information generator comprises:
a memory storing the first information and the second information;
a first multiplier coupled to the memory, and multiplying the first DC gain by the first information to generate first data;
a second multiplier coupled to the memory, and multiplying the second DC gain by the second information to generate second data;
a first adder adding the first data and the second data to generate the first compensation information.

10. The AFE circuit according to claim 9, further comprising:
a second amplifier;
a second compensation circuit coupled to an output terminal of the second amplifier, correcting an output voltage generated by the second amplifier according to second compensation information; and
the compensation information generator coupled to the second compensation circuit and generating the second compensation information according to a third DC gain, a fourth DC gain, third information and fourth information,
wherein the third information is generated based on a third offset voltage generated by a tail current source of the second amplifier and the second information, and the fourth information is generated based on a fourth offset voltage generated by a differential input transistor pair of the second amplifier and the second information.

11. The AFE circuit according to claim 10, wherein the compensation information generator further comprises:
a third multiplier coupled to the memory, and multiplying the third DC gain by the third information to generate third data;
a fourth multiplier coupled to the memory, and multiplying the fourth DC gain by the fourth information to generate fourth data; and
a second adder adding the third data and the fourth data to generate the second compensation information.

12. The AFE circuit according to claim 10, further comprising:
a comparator coupled after the first amplifier,
wherein the second amplifier is coupled before the first amplifier.
